(19) United States
(12) Patent Application Publication
(10) Pub. No.: US 2003/0132472 A1
(43) Pub. Date: Jul. 17, 2003

(54) Semiconductor device with a ferroelectric memory provided on a semiconductor substrate

(76) Inventor: Satoshi Koizumi, Miyagi (JP)

Correspondence Address: VOLENTINE FRANCOS, PLLC, Suite 150, 12200 Sunrise Vally Drive, Reston, VA, 20191, US

(21) Appl. No.: 10/284,188

(22) Filed: Oct. 31, 2002

(30) Foreign Application Priority Data
Jan. 15, 2002 (JP) 005975/2002

(51) Int. Cl. H01L 27/108

(52) U.S. Cl. 257/296

(57) ABSTRACT

A semiconductor device is provided with a ferroelectric memory formed on a semiconductor substrate. The ferroelectric memory has transistors including a first electrode, a second electrode, and a control electrode, and capacitors including a lower electrode, a ferroelectric film, and an upper electrode. The semiconductor device is further provided with a first wiring layer for electrically connecting the upper electrode to either the first electrode or the second electrode, and an oxide film formed by oxidation treatment of the first wiring layer, the oxide film having a film thickness not less than twice and not more than eight times as thick as a natural oxide film of the first wiring layer.

### BACKGROUND OF THE INVENTION

The invention relates to a semiconductor device, and particularly, to a nonvolatile memory.

While advances have been made in high-integration of various semiconductor memories in recent years, attention is being focused particularly on a ferroelectric memory functioning as a nonvolatile memory. The ferroelectric memory is a memory employing a ferroelectric film in a capacitor for storing and maintaining charge, utilizing the function of ferroelectrics for reversing electric fields due to spontaneous polarization thereof, and maintaining the same. The ferroelectric memory has a cell structure comprising, for example, transistors and ferroelectric capacitors.

As an example of a constitution of such a ferroelectric memory cell, there is cited a 2T2C (2Transistors2Capacitors) type memory cell made up of two transistors and two ferroelectric capacitors. The 2T2C type memory cell operates stably because of its excellent resistance against fatigue causing an amount of polarization of the capacitors to be decreased depending on the number of times data are rewritten. However, this type of memory cell is not suited for high-integration because of a large area occupied by one memory cell.

Accordingly, researches on high-integration of a 1T1C type memory cell are carried out, however, there are many problems encountered in securing stable operation of the 1T1C type memory cell as matters stand now.

Consequently, researches on downsizing of an area occupied by one memory cell have since been conducted while giving consideration to a constitution of memory cells such as the 1T1C type, the 2T2C type, and so forth.

On the other hand, researches have also been conducted for achieving more complex functions by assembling a ferroelectric memory into a logic LSI, that is, by placing the ferroelectric memory and the logic LSI together on one and the same substrate.

In the case of placing the ferroelectric memory and the logic LSI together on the very same substrate, however, the ferroelectric memory is exposed to heat treatment in a reducing atmosphere, applied in a process of manufacturing the logic LSI. The heat treatment in the reducing atmosphere is applied in the steps of fabricating an interlayer insulator, a passivation film, a mould, and so forth, respectively, which are carried out in a hydrogen (H₂) gas-bearing atmosphere. Consequently, it is well known that a ferroelectric film making up a ferroelectric capacitor is subjected to the effect of the heat treatment in the reducing atmosphere, thereby causing deterioration in the characteristic (hereinafter referred to merely as ferroelectricity) of the ferroelectric film.

Hence, there has been proposed a method of preventing deterioration in ferroelectricity by covering the surface of the ferroelectric capacitor with a cover film made of tantalum oxide (TaO), aluminum oxide (AlO), or titanium oxide (TiO) to thereby protect the ferroelectric film.

The method, however, poses a problem of complicating manufacturing steps owing to the need for preparing a mask and so forth, for used in fabrication of the cover film in addition to problems such as unstable film quality of the cover film (TaO etc.), or difficulty with processing of films (AlO, TiO, etc.) by etching, and so forth, to be performed in later steps of processing.

Firstly, it has since been revealed that the ferroelectric film made of a metal oxide undergoes reduction in the reducing atmosphere described above, thereby causing deterioration in ferroelectricity due to fatigue occurring to the ferroelectric film.

Secondly, it has since been revealed that a metal wiring layer of a multilayered wiring structure, fabricated when forming the ferroelectric memory, undergo oxidation by the agency of moisture contained in an interlayer insulator formed in such a way so as to be in contact with the metal wiring layer, so that deterioration in ferroelectricity of the ferroelectric memory is also caused to occur by the agency of hydrogen evolved due to such oxidation.

Practically, however, it is difficult to apply heat treatment in an oxidizing atmosphere to the ferroelectric memory with deteriorated ferroelectricity in order to restore original ferroelectricity.

Thirdly, a cause for deterioration in ferroelectricity has been sought taking note of the fact that the ferroelectric film is made of a piezoelectric material having, piezoelectricity. As a result, it has been revealed that the interlayer insulator formed so as to be in contact with the ferroelectric film is formed even so as to have compressive stress in order to prevent occurrence of cracks caused by moisture absorption and stress, so that there occurs polarization to the ferroelectric film upon contact thereof with the interlayer insulator, thereby causing deterioration in ferroelectricity

### SUMMARY OF THE INVENTION

A semiconductor device according to the invention is provided with a ferroelectric memory on a substrate thereof. The ferroelectric memory has transistors including a first electrode, a second electrode, and a control electrode, and capacitors including a lower electrode, a ferroelectric film, and an upper electrode. The semiconductor device is further provided with a first wiring layer for electrically connecting the upper electrode to either the first electrode or the second electrode, and an oxide film formed by oxidation treatment of the first wiring layer, the oxide film having a film thickness not less than twice and not more than eight times as thick as a natural oxide film of the first wiring layer.

### BRIEF DESCRIPTION OF THE DRAWINGS

FIGS. 1(A) to 1(C) are schematic views illustrating steps of a first embodiment of a method of fabricating a semiconductor device according to the invention;

FIGS. 2(A) and 2(B) are schematic views illustrating steps of the first embodiment of the method of fabricating the semiconductor device according to the first embodiment, following those shown in FIG. 1;

FIG. 3 is a schematic view illustrating a step of a second embodiment of a method of fabricating a semiconductor device according to the invention;

FIGS. 4(A) to 4(C) are schematic views illustrating steps of a third embodiment of a method of fabricating a semiconductor device according to the invention;

FIG. 5 is a schematic view illustrating a step of a fourth embodiment of a method of fabricating a semiconductor device according to the invention; and

FIGS. 6(A) to 6(C) are schematic partial plan views illustrating the semiconductor device according to the respective embodiments of the invention.

### DESCRIPTION OF THE PREFERRED EMBODIMENTS

Preferred embodiments of the invention are described hereinafter with reference to the accompanying drawings. It is to be pointed that respective figures broadly show a shape, size, and disposition relation of respective constituent parts merely to such an extent as to enable the invention to be better understood, and accordingly, the scope of the invention is not limited to the embodiments shown in these figures. In some of the figures, referred to as a plan view, underlying members and lines out of sight, due to the construction of an embodiment, are not shown. Further, hatching (diagonals) indicating sections are omitted except for some portions for the sake of simplification. Description given hereinafter is concerned merely with the preferred embodiments of the invention, and the invention is not limited in any way to numerical conditions given therein by way of example.

There is described hereinafter by way of example a semiconductor device comprising a stacked multilayer body formed by assembling principal constituent elements of a transistor onto a common substrate, and a ferroelectric capacitor provided on the stacked multilayer body. Accordingly, before describing respective embodiments of the invention, the stacked multilayer body and the ferroelectric capacitor, common to the respective embodiments, are broadly described.

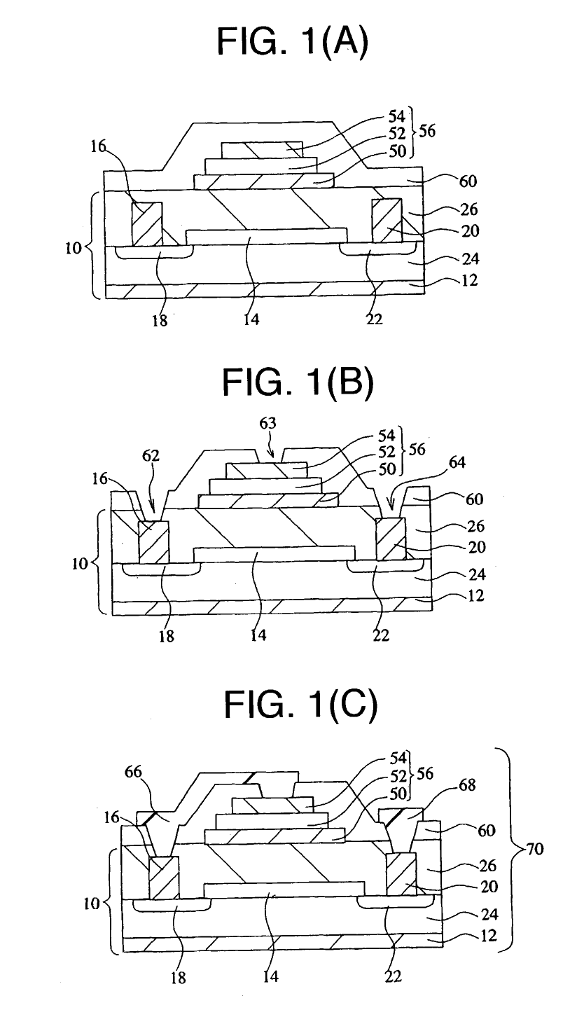

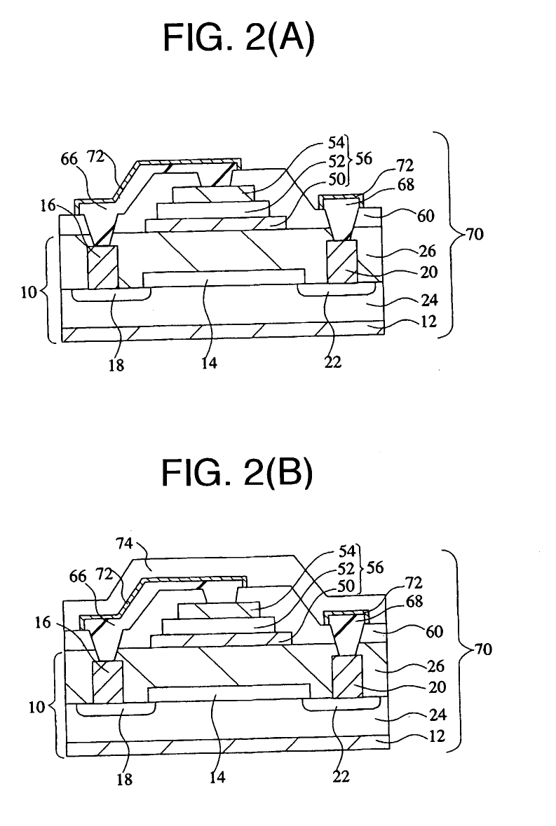

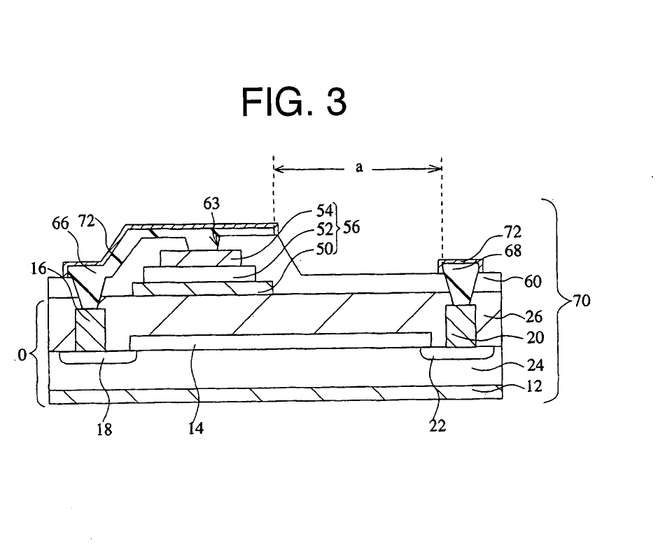

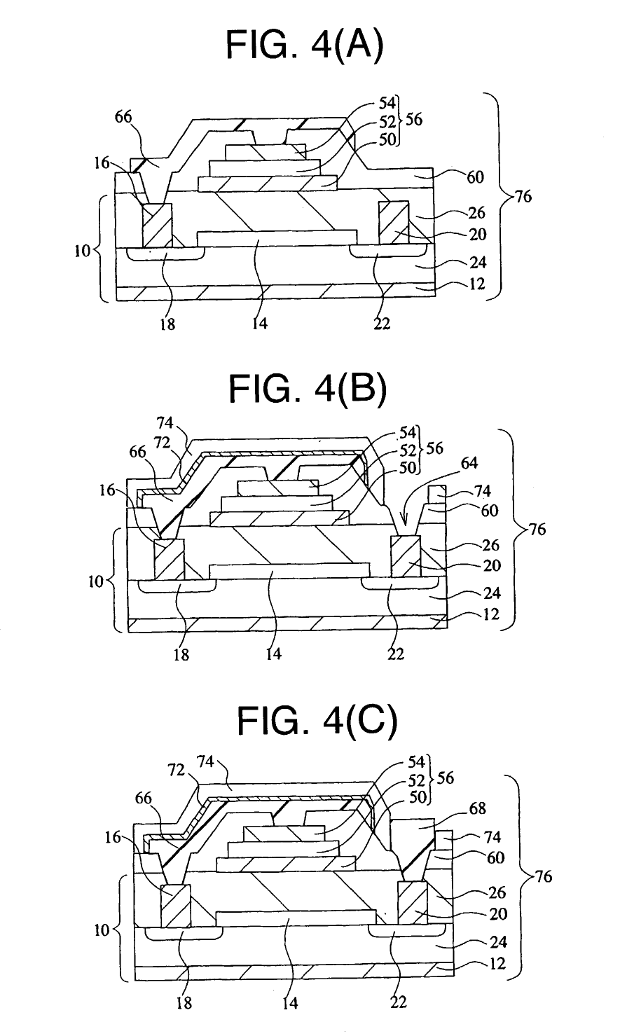

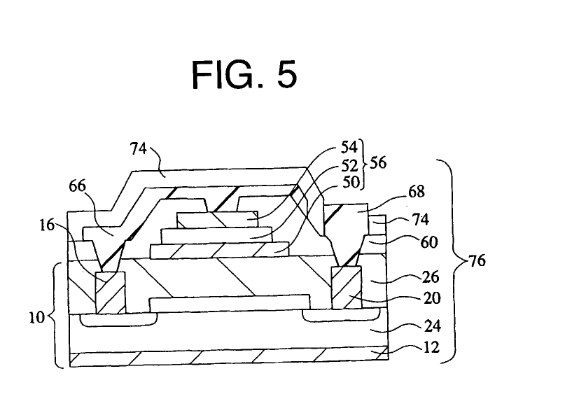

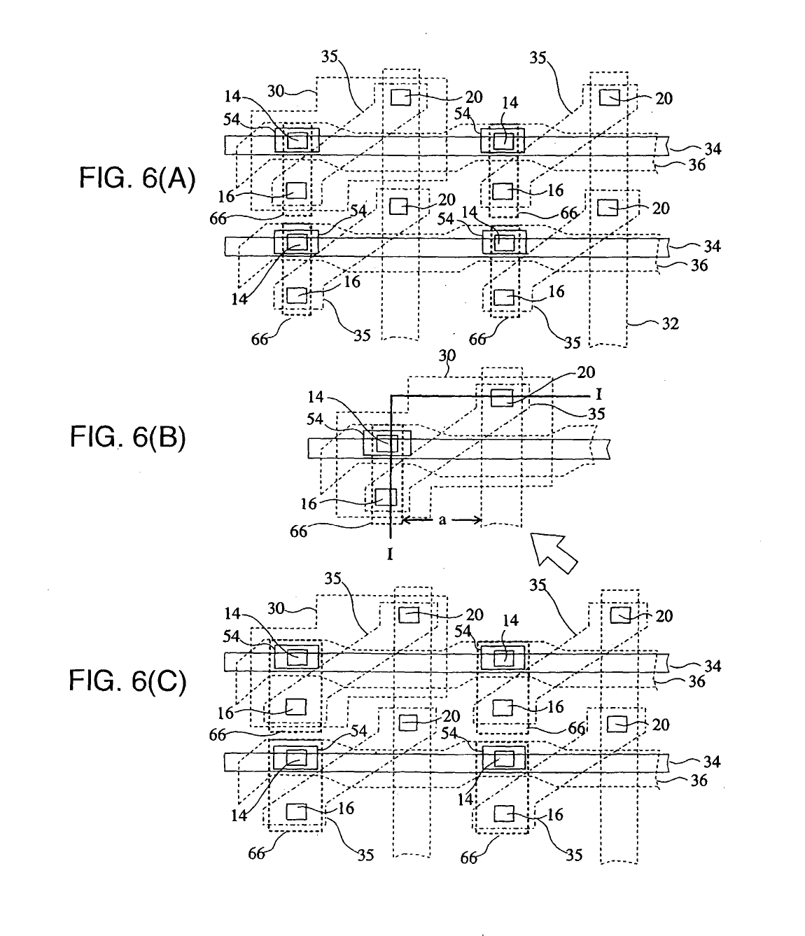

FIGS. 1 and 2 are schematic views illustrating steps of a first embodiment of a method of fabricating a semiconductor device according to the invention. FIG. 3 is a schematic view illustrating a step of a second embodiment of a method of fabricating a semiconductor device according to the invention, FIGS. 4(A) to 4(C) are schematic views illustrating steps of a third embodiment of a method of fabricating a semiconductor device according to the invention, and FIG. 5 is a schematic view illustrating a step of a fourth embodiment of a method of fabricating a semiconductor device according to the invention. Further, FIGS. 6(A) to 6(C) are schematic plan views illustrating the respective embodiments. It is to be understood that various layers and structures, shown in FIGS. 1 to 6, are not necessarily drawn by expanding these at a given ratio. Further, in the figures, there are not shown a logic LSI, a sense amplifier, and so forth, that are placed on the same substrate along with the ferroelectric capacitor.

Now, a stacked multilayer body 10 as shown by way of example in FIGS. 1 to 5 is made up as follows. That is, the stacked multilayer body 10 comprises a substrate 12, and a semiconductor layer, for example, a silicon layer 24, provided on the substrate 12. A source region (source electrode) 18 and a drain region (drain electrode) 22 are formed in the silicon layer 24, and a gate electrode 14 for interconnecting both the regions is formed on top of the silicon layer 24. Further, a tungsten (W) plug 16 (referred to hereinafter merely as tungsten plug 16) connected to the source region 18, and a tungsten plug 20 (referred to hereinafter merely as tungsten plug 20) connected to the drain region 22 are formed. An insulating layer 26 made of silicon oxide (SiO₂) is formed on top of the silicon layer 24 in such a way as to cover the respective electrodes, and contact holes 62, 64, for exposing the top face of tungsten plugs 16, 20, respectively, are formed in the insulating layer 26. The stacked multilayer body 10 comprised as described above constitutes a MOSFET (metal oxide semiconductor field effect transistor). For the MOSFET, either an n-channel MOSFET or a p-channel MOSFET may be suitably selected for use.

A ferroelectric capacitor 56 is provided, for example, above the gate electrode 14, and comprises a lower electrode 50, a ferroelectric film 52, and an upper electrode 54, sequentially formed in that order on top of a planarized surface of the insulating layer 26.

Now, there are described hereinafter preferred embodiments of a semiconductor device according to the invention, comprising the ferroelectric capacitor formed on the stacked multilayer body.

A first embodiment of the invention is described with reference to FIGS. 1, 2 and FIGS. 6(A), 6(B).

FIGS. 1 and 2 are schematic sectional views showing a cut face, respectively, of a ferroelectric memory cell array shown in a schematic plan view of FIG. 6(A), taken on solid line I-I in FIG. 6(B), as seen from the direction of the arrow in FIG. 6(B).

As shown in FIG. 6(A), a ferroelectric memory comprising the stacked multilayer body 10 is connected to a bit line 32, a word line 34, and a plate line 36, which are three controllable lines. Further, the tungsten plug 20 connected to the drain region 22 of respective transistors, comprised of the source region 18, the drain region 22, and the gate electrode 14, is connected to the bit line 32, and the gate electrode 14 is connected to the word line 34. An active region 35 is a region surrounded by a dotted line in the figure.

The upper electrode 54 is provided above the gate electrode 14 (the ferroelectric film and the lower electrode are sequentially formed in that order underneath the upper electrode although not shown in the figure). The upper electrode 54 is connected to the source region 18 via a first wiring layer 66 to be formed by a method according to the respective embodiments described hereinafter.

In a first step, there is first formed the first wiring layer 66 for electrically connecting the upper electrode 54 of the respective ferroelectric capacitors 56 to the source region 18 serving as a first electrode of the respective transistors or the drain region 22 serving as a second electrode of the respective transistors.

As described in the foregoing, the respective resistors comprise the first electrode (source region) 18, the second electrode (drain region) 22, and a control electrode (the gate electrode) 14, provided on the substrate 12. The respective ferroelectric capacitors 56 comprise the lower electrode 50, the ferroelectric film 52, and the upper electrode 54.

Herein, the formation of the ferroelectric capacitor 56 is briefly described.

First, the lower electrode 50 is formed on top of the stacked multilayer body 10. With a constitution described herein, a platinum electrode is used for the lower electrode 50, and is processed by, for example, a suitable sputtering method using a platinum target and an etching method, which are normally adopted in forming an electrode, thereby forming the lower electrode 50 to a thickness about 200 nm.

Subsequently, the ferroelectric film 52 is formed on top of the lower electrode 50. With the constitution described herein, a coating film of SrBi₂Ta₂O₉ is formed on top of the lower electrode 50 by, for example, any suitable spin coater method. Thereafter, after the coating film is dried and solvents contained therein are evaporated, tentative baking is applied to the coating film to thereby burn organic functional groups. Subsequently, full-scale baking is applied thereto, and a SrBi₂Ta₂O₉ film about 200 nm in thickness, serving as the ferroelectric film 52, is formed. It is to be pointed out that the ferroelectric film is not limited to a SrBi₂Ta₂O₉ film, but other films made of, for example, PbZrTiO₃, BaₓSr₁₋ₓTiO₃, Pb₅Ge₃O₁₁, and Bi₄Ti₃O₁₂, respectively, can be used for the ferroelectric film according to the invention.

Thereafter, the upper electrode 54 is formed on top of the ferroelectric film 52. A platinum electrode about 200 nm in thickness, serving as the upper electrode 54, is formed by, for example, the same method as that adopted for the formation of the lower electrode 50.

Thus, the ferroelectric capacitor 56 as shown in FIG. 1(A) is formed. A shape of the ferroelectric capacitor 56 is not limited to the shape shown in the figure, and any shape of the ferroelectric capacitor 56 will do as long as the same is made up so as to function satisfactorily as the ferroelectric capacitor 56.

Subsequently, an insulating film 60 covering the surface of the stacked multilayer body 10 incorporating the ferroelectric capacitor 56 is formed (refer to FIG. 1(A)). The insulating film 60 is formed to a thickness about 400 nm on top of the stacked multilayer body 10 by any suitable CVD method. The insulating film 60 is made up of, for example, a silicon oxide film.

Thereafter, there are formed contact holes 62, 63 for electrically connecting the upper electrode 54 to the source region 18 serving as the first electrode, and a contact hole 64 for electrically connecting the drain region 22 serving as the second electrode to an sense amplifier (not shown) provided outside of a ferroelectric memory cell 30 to thereby form the bit line by any suitable dry etching method, respectively (refer to FIG. 1(B)).

Subsequently, a provisional wiring layer (not shown) is formed on top of the insulating film 60 in such a way as to fill up these contact holes 62, 63, and 64. The provisional wiring layer is formed to a thickness about 400 nm by any suitable sputtering method using, for example, any one selected the group consisting of Al, Ti, TiN, an alloy containing at least one of these metals (for example, an alloy composed of Al (aluminum), Si (silicon), and Cu (copper) and an alloy composed of Al and Cu).

Thereafter, a first wiring layer 66 and a second wiring layer 68 are formed by applying any suitable etching method to the provisional wiring layer, thereby obtaining a structure 70 provided with these wiring layers 66, 68. The structure 70 is shown in FIG. 1(C).

Next, in a second step, the first and second wiring layers 66, 68 are subjected to an oxidation treatment, and an oxide film of the first and second wiring layers 66, 68, respectively, is formed on an exposed face thereof to a thickness not less than twice and not more than eight times as thick as a natural oxide film thereof.

It is well known that the first wiring layer 66 of the structure 70 shown in FIG. 1(C), for example, an aluminum film, has a natural oxide film normally in the order of 5 nm in thickness. However, with the natural oxide film in the order of 5 nm in thickness, there occurs diffusion of hydrogen (H2) in the first wiring layer 66, so that it is not possible to avoid deterioration in ferroelectricity. It has been revealed that there is therefore the need for forming the oxide film with a thickness at least not less than twice as thick as the natural oxide film in order to prevent undesirable diffusion of hydrogen.

Accordingly, by applying an oxidation treatment to the first wiring layer and the second wiring layer (66, 68), an oxide film 72 is formed in the surface layer of the respective wiring layers (66, 68). In this connection, the oxidation treatment is executed by any suitable method such as an oxygen plasma method, a fast heat treatment method, and so forth. In the case of the oxygen plasma method, a heat treatment is applied by placing the structure 70 inside, for example, a parallel plate plasma chamber system, and by introducing an O₂ gas for several minutes on conditions at about 420° C. under a reduced pressure at about 800 Torr. In the case of the fast heat treatment method, a heat treatment is applied by placing the structure 70, for example, under the atmospheric pressure, raising temperature up to 800° C. at a warming rate of 100° C./sec in an O₂ gas (pure oxygen gas or a mixed gas of O₂ and nitrogen (N2)) atmosphere, and maintaining such conditions for several seconds.

FIG. 2(A) shows a state in which the oxide film 72 is formed to a thickness, for example, 20 nm on the surface of the first and second wiring layers (66, 68) by the oxidation treatment applied to the surface.

With the present embodiment, the oxide film 72 is formed to the thickness 20 nm, however, according to the invention, the oxide film can be formed to a thickness 2 to 8 times as thick as the natural oxide film (thickness: about 5 nm), that is, to a thickness in a range of 10 to 40 nm. Further, a film thickness of the oxide film 72 is in such a range as will enable diffusion of hydrogen into the first wiring layer 66 to be blocked, and can be obtained by giving consideration to possibility of complication in processing occurring due to longer time required for the heat treatment. The oxide film 72 is preferably formed to a thickness in a range of 15 to 25 nm, and more preferably, to a thickness 20 nm.

Thereafter, an insulating film 74 is provided in such a way as to cover the entire upper side of the stacked multilayer body 10 incorporating the first and second wiring layers 66, 68, with the oxide film 72 formed thereon. The insulating film 74 made up of, for example, a silicon oxide film is formed by any suitable CVD method. The insulating film 74 is formed to a thickness, for example, about 500 nm. The insulating film 74 can be used as an interlayer insulator (refer to FIG. 2(B)).

As is evident from the foregoing description, with the present embodiment, the oxide film 72 is formed on the first wiring layer 66 for electrically connecting the upper electrode 54 to the source region 18 as the first electrode. The diffusion of hydrogen into the first wiring layer 66 can be blocked by the agency of the oxide film 72, so that it is possible to suppress exposure of the ferroelectric film 52 to hydrogen, occurring in a reducing atmosphere included in a manufacturing process of a logic LSI.

Further, because the oxide film 72 (for example, an aluminum oxide film, a titanium oxide film, etc.) that is formed through oxidation of the constituent material of the first and second wiring layers (66, 68) described above has stable film quality, there is involved no risk of the film quality being altered in back-end steps of processing.

Now, according to a second embodiment of the invention, in a first step corresponding to the first step of the first embodiment, a first wiring layer is formed so as to cover an upper electrode in whole from the upper side thereof.

With the second embodiment, the first wiring layer 66 is formed so as to overlie an upper electrode 54 on the upper side thereof such that the upper electrode 54 is hidden below the first wiring layer 66 when looking at the upper electrode 54 from the side of the first wiring layer 66. Consequently, the first wiring layer 66 is formed in a region congruent with or larger than that for the upper electrode 54.

After the formation of the first wiring layer 66, an oxide film 72 is formed in a second step similar to that of the first embodiment (refer to FIG. 3).

As is evident from the foregoing description, with the present embodiment, similar advantageous effects to those for the first embodiment can be obtained.

Further, with the present embodiment, compression stress, occurring to an oxide film 74 (refer to FIG. 2(B)), and so forth, formed over the first wiring layer 66 in later steps, is dispersed in the first wiring layer 66 by the agency of the first wiring layer 66 formed so as to cover the upper electrode 54 in whole from the upper side thereof, and an adverse effect of the compression stress on a ferroelectric film 52 can be mitigated, so that deterioration in ferroelectricity can be further suppressed.

With the present embodiment, however, as is evident from the schematic plan view (refer to FIG. 6(C)) of a ferroelectric memory cell array, there is the need for providing an area occupied by the ferroelectric memory cell 30, larger than that (refer to FIG. 6(A)) for the first embodiment. The reason for this is because there is the need of maintaining a spacing (spacing indicated by “a” in to FIG. 6(B)) between the first and second wiring layers (66, 68), which are formed at the same time as described with reference to the first embodiment, at a given distance, taking into consideration possibility of short circuit and so forth.

With a third embodiment of the invention, in a first step corresponding to the first step of the first embodiment, a first wiring layer is formed so as to cover an upper electrode from the upper side thereof.

The present embodiment is similar in constitution to the second embodiment in that the upper electrode 54 is covered by, and hidden below the first wiring layer 66 as seen from the upper side, however, this region can be formed without enlarging an area occupied by a ferroelectric memory cell region.

In a first step, there is first formed an insulating film 60 to a thickness about 400 nm on top of a stacked multilayer body 10 as shown in FIG. 1(A).

Thereafter, with the present embodiment, there is formed only a contact hole 62 for electrically connecting the upper electrode 54 to a source region 18 serving as a first electrode. Then, following steps similar to those of the first embodiment, a structure 76 provided with the first wiring layer 66 of a size large enough to cover and shield the upper electrode 54 is formed as shown in FIG. 4(A).

Thereafter, in a second step, an oxide film 72, 20 nm in thickness, is formed by applying an oxidation treatment to the surface of the first wiring layer 66 by the same method as that in the case of the first embodiment.

Subsequently, after the second step according to the present embodiment, there is formed a second wiring layer for electrically connecting whichever electrode (unconnected) of the first and second electrodes, not connected to the upper electrode, to the outside of the structure 76.

More specifically, after an insulating film 74 made up of a silicon oxide film is formed to a thickness about 500 nm over a stacked multilayer body 10, a contact hole 64 for electrically connecting a drain region 22 serving as the second electrode to an sense amplifier (not shown) provided outside of a ferroelectric memory cell (refer to FIG. 4(B)). Then, the second wiring layer 68 as shown in FIG. 4(C) is formed.

As is evident from the foregoing description, with the present embodiment, similar advantageous effects to those for the second embodiment can be obtained.

Furthermore, with the present embodiment, the first wiring layers 66 and the second wiring layer 68 are formed separately from each other, and consequently, there is no risk of short circuit occurring between the first wiring layers 66 and the second wiring layer 68 even with adoption of a layout such that the upper electrode 54 is covered and shielded by the first wiring layer 66. Accordingly, the present embodiment can be implemented with the same area occupied by the ferroelectric memory cell region as that for the first embodiment, thus eliminating any fear of an increase in a chip area.

With a fourth embodiment of the invention, a constitution is adopted wherein no oxidation treatment is applied to the first wiring layer 66 obtained in the first step for the third embodiment. After an insulating film 74 is formed to a thickness about 500 nm, a contact hole 68 is formed as with the case of the third embodiment, thereby forming a second wiring layer 68 (refer to FIG. 5).

As is evident from the foregoing description, with the present embodiment, an adverse effect of compression stress of the insulating film 74 (refer to FIG. 2(B)), formed over the first wiring layer 66 in a later step, on a ferroelectric film 52 can be mitigated by the agency of the first wiring layer 66 formed so as to cover the upper electrode 54 in whole, so that deterioration in ferroelectricity can be suppressed.

Further, as with the case of the third embodiment, since the first wiring layer 66 and the second wiring layer 68 are formed separately from each other, there is no fear of an increase in a chip area.

Now, it is to be pointed out that the above-described conditions and so forth of the preferred embodiments of the invention are not limited to the combinations described hereinbefore. Accordingly, the invention can be carried out by combining suitable conditions in any suitable stages.

Further, the stacked multilayer body is not limited in shape to the above-described constitution, so that the invention can be carried out with any other constitution. That is, a silicon layer itself, for example, may be used as the substrate.

As is evident from the foregoing description, the invention can provide a highly reliable ferroelectric memory by fabricating a structure capable of suppressing deterioration in ferroelectricity in the steps of manufacturing the ferroelectric memory.

The present invention can apply to the method of manufacturing a semiconductor device. The method may include a first step and a second step. The first step is forming a ferroelectric memory comprising a stacked multilayer body incorporating transistors comprising a first electrode, a second electrode, and a control electrode, provided on a substrate of the stacked multilayer, and capacitors comprising a lower electrode, a ferroelectric film, and an upper electrode, and forming a first wiring layer for electrically connecting the upper electrode to either the first electrode or the second electrode. The second step is forming an oxide film to a thickness not less than twice and not more than eight times as thick as a natural oxide film of the first wiring layer on top of the surface thereof by oxidation treatment of the first wiring layer.

In the method, the first wiring layer can be formed so as to cover and shield the upper electrode from the upper side in the first step. A second wiring layer connects any electrode of the first electrode and the second electrode, doesn't connected to the upper electrode, to the outside is formed after the second step.

Further, the oxide film is formed to a thickness not less than 10 nm and not more than 40 nm.

The oxide film is formed to a thickness 20 nm.

Another method of manufacturing a semiconductor device can be applied to the present invention. The method also includes the first and second steps. The first step is forming a ferroelectric memory comprising a stacked multilayer body incorporating transistors comprising a first electrode, a second electrode, and a control electrode, provided on a substrate of the stacked multilayer, and capacitors comprising a lower electrode, a ferroelectric film, and an upper electrode, and forming a first wiring layer for electrically connecting the upper electrode to either the first electrode or the second electrode in such a way as to cover and shield the upper electrode from the upper side. The second step is forming a second wiring layer for electrically connecting any electrode of the first electrode and the second electrode, not connected to the upper electrode, to the outside.

What is claimed is:

1. A semiconductor device with a ferroelectric memory provided on a semiconductor substrate, comprising:
a plurality of transistors comprising a first electrode, a second electrode, and a control electrode; and
a plurality of capacitors comprising a lower electrode, a ferroelectric film, and an upper electrode, wherein there are provided a first wiring layer for electrically connecting the upper electrode to either the first electrode or the second electrode, and an oxide film formed by oxidation treatment of the first wiring layer, the oxide film having a film thickness not less than twice and not more than eight times as thick as a natural oxide film of the first wiring layer.

2. The semiconductor device according to claim 1, wherein the first wiring layer is formed so as to cover and shield the upper electrode without exposing the same.

3. The semiconductor device according to claim 1, wherein the oxide film has a film thickness not less than 10 nm and not more than 40 nm.

4. The semiconductor device according to claim 1, wherein the oxide film has a film thickness 20 nm.

5. A semiconductor device with a ferroelectric memory provided on a substrate thereof; said ferroelectric memory comprising:
a plurality of transistors comprising a first electrode, a second electrode, and a control electrode; and
a plurality of capacitors comprising a lower electrode, a ferroelectric film, and an upper electrode, wherein there is provided a first wiring layer formed so as to cover and shield the upper electrode from the upper side.
